(19) United States
(12) Patent Application Publication
(10) Pub. No.: US 2024/0300821 A1
(43) Pub. Date: Sep. 12, 2024

(54) ELECTROSTRICTIVE MATERIALS BASED ON DOPED CERIA

(71) Applicant: YEDA RESEARCH AND DEVELOPMENT CO. LTD., Rehovot (IL)

(72) Inventors: Igor LUBOMIRSKY, Petach-Tikva (IL); Maxim VARENIK, Rehovot (IL)

(73) Assignee: YEDA RESEARCH AND DEVELOPMENT CO. LTD., Rehovot (IL)

(21) Appl. No.: 18/668,340

(22) Filed: May 20, 2024

Related U.S. Application Data
(63) Continuation-in-part of application No. PCT/IL2022/051236, filed on Nov. 21, 2022.

(30) Foreign Application Priority Data
Nov. 21, 2021 (IL) 288274

(51) Int. Cl. C01F 17/235; C01G 25/00

(52) U.S. Cl. CPC C01F 17/235; C01G 25/006; C01P 2002/52; C01P 2004/03; C01P 2006/40

(57) ABSTRACT

This invention provides doped ceria-based materials exhibiting electrostriction properties and methods of preparation thereof.

### CROSS REFERENCE TO RELATED APPLICATIONS

This application is a Continuation in part of PCT International Application No. PCT/IL2022/051236, filed Nov. 21, 2022; claiming the benefit of Israeli Patent Application No. 288274, filed Nov. 21, 2021, which are hereby incorporated in their entirety herein by reference.

### FIELD OF THE INVENTION

This invention provides doped ceria-based materials exhibiting electrostriction properties and methods of preparation thereof.

### BACKGROUND OF THE INVENTION

Materials that can develop significant strain in response to electric fields are used in microfabrication as actuators, sensors, and transducers. These materials are either piezoelectric (strain proportional to electric field) or electrostrictive (strain proportional to electric field squared). Although piezoelectric materials are more prevalent, they can suffer from feedback in electrical systems due to the direct piezoelectric effect and low repeatability due to hysteresis and creep. Electrostrictors do not have a converse effect and thus have advantages in certain applications. The majority of commonly used electrostrictive ceramics are based on lead manganese niobate. These ceramics display large electrostriction strain coefficients ˜10⁻¹⁶ m²/V² at frequencies of up to a few kHz.

However, they suffer from two major drawbacks: (1) large dielectric constants (>10,000) which require high driving currents and cause very high electrical losses; and (2) incompatibility with thin-film silicon-microfabrication techniques. Moreover, the use of PMN is limited due to the presence of lead (toxic).

Doped ceria exhibits a very high electrostriction coefficient (10⁻¹⁶ m²/V²), higher than predicted by classical theory. Ceria is also much more compatible with microfabrication processes and has a very low dielectric constant (˜30). Unfortunately, the high electrostriction coefficient is achieved only at low frequencies (<1 Hz). In addition, at these frequencies, strain saturates (does not increase further) at values of ˜10 ppm. At higher frequencies the electrostriction coefficient relaxes by at least an order of magnitude to 10⁻¹⁸-10⁻¹⁷ m²/V².

### SUMMARY OF THE INVENTION

Aliovalent doped ceria exhibits electrostriction coefficients >100-fold larger than estimated on the basis of Newnham's scaling law for classical electrostrictors, despite ceria's large Young's modulus (˜200 GPa) and low dielectric constant (<30). This “non-classical” behavior has been attributed to the formation of highly polarizable, elastic dipoles reorienting under external electric field.

The high frequency electrostriction coefficient was found to increase with decreasing dopant ionic radius, with the smallest ionic radius lanthanide (Lu) having a high frequency electrostriction constant of 8·10⁻¹⁸ m²/V². No smaller dopants have been previously explored.

In an embodiment of this invention, it was found that, 10 mol % Zr⁴⁺-doped ceria, wherein the ceria is oxidized, displays an electrostriction coefficient of |M₃₃|≈10⁻¹⁶ m²/V² throughout the 0.1 Hz-3000 Hz frequency range. However, practical application of these ceramics may be hindered by the relatively large, room-temperature electrical conductivity (10⁻¹⁰ S/m), a result of the formation of Ce³⁺ which can promote electron hopping. Formation of Ce³⁺ also raises the dielectric constant to ˜200. Suppression of Ce³⁺ by co-doping (e.g. doping ceria with Zr and co-doping with an additional cation such as Yb or La, or a combination thereof) reduces the dielectric constant to ˜30 but also reduces the electrostriction constant to ˜10⁻¹⁷ m²/V². In one embodiment, the presently disclosed subject matter shows that by systematically adjusting the composition of ceria-based solid solutions, technologically useful electrostrictive materials can be formed, being fully compatible with silicon microfabrication.

Accordingly and in one embodiment, this invention provides a 10 mol % Zr-doped ceria material (10 mol % Zr⁴⁺) displaying 10⁻¹⁶ m²/V² throughout the 0.1-150 Hz frequency range, with no apparent strain saturation reaching strain of up to 200 ppm. However, as a result of spontaneous partial reduction (Ce⁴⁺ to Ce³⁺) the dielectric constant and electrical conductivity both increase by an order of magnitude (see herein above). In some embodiments, this can be partially remedied by co-doping with lanthanides. Without being bound to any theory, it is suggested herein that elastic dipoles induced in ceria ceramics by small dopants, give stronger electrostrictive response at high frequencies (>10 Hz). Such an electrostrictive response is higher than the response obtained when using larger dopants, regardless of dopant charge.

In one embodiment, this invention provides a ceria-based material, doped by a metal M, the metal M is selected from Hf, Zr and Ti, wherein upon application of an electric field the ceria-based material generates displacement, stress or a combination thereof.

In one embodiment, the presently disclosed subject matter provides a ceria-based material, doped by a metal M, the metal M is selected from Hf, Zr and Ti, wherein upon application of an electric field said ceria-based material generates displacement, stress or a combination thereof, wherein the electrostriction coefficient of said material ranges between 10⁻¹⁵ m²/V² and 10⁻¹⁸ m²/V² at a frequency ranging between 0.1 Hz and 105 Hz.

In one embodiment, the material is represented by the formula Ce₁₋ₓMₓO₂, wherein x ranges between 0.02 and 0.7. In one embodiment the material is represented by the formula Ce₁₋ₓMₓO_{2-d}. In one embodiment the material is represented by the formula Ce₁₋ₓMₓO_{2-d} wherein x ranges between 0.02 and 0.7 and d ranges between 0 and 0.03. In one embodiment the material is co-doped with a metal with a lower valence than metal M. In one embodiment the lower valence metal is selected from: Ca, Mg, Fe, Sc, Sn and Y or combinations thereof. In one embodiment, the material is co-doped with a lanthanide L. In one embodiment, the lanthanide L is any lanthanide selected from La, Pr, Nd, Pm, Sm, Eu, Gd, Tb, Dy, Ho, Er, Tm, Yb and Lu or any combination thereof.

In one embodiment, the ceria-based material is represented by the formula Ce_{1-x-y} MₓL_{y}O_{2-y/2}, wherein x ranges between 0.01-0.7 and y range between 0.01-0.7. In one embodiment, L is La or Yb. In one embodiment, L is La, x=0.10±0.02 and y=0.10±0.02. In one embodiment the ceria-based material is represented by the formula Ce_{1-x-y} MₓL_{y}O_{2-y/2-d}, and wherein x ranges between 0.01-0.7, y range between 0.01-0.7 and d ranges between 0 and 0.03.

In one embodiment, the displacement that the ceria-based material generates ranges between 0.1 ppm and 500 ppm. In one embodiment, the stress that the ceria-based material generates is at least 0.01 MPa. In one embodiment, the Young's modulus of the material ranges between 100 GPa and 250 GPa.

In one embodiment, the electrostriction coefficient of the material ranges between 10⁻¹⁵ m²/V² and 10⁻¹⁸ m²/V². In one embodiment, the electrostriction coefficient of the material ranges between 10⁻¹⁵ m²/V² and 10⁻¹⁸ m²/V² at a frequency ranging between 0.1 Hz and 105 Hz. In one embodiment, the electrostriction coefficient is frequency independent.

In one embodiment, the dielectric constant of the material ranges between 10 and 1000. In one embodiment, the electrical conductivity of the material ranges between 10⁻⁹ S/m and 10⁻⁵ S/m.

In one embodiment, the material form of the ceria-based material is selected from: a disk, a film, a powder, a bar a pellet or any combinations thereof. In one embodiment, the thickness of the disk, film, bar or pellet ranges between 0.1 mm and 10 mm. In one embodiment, the material is a single crystal, polycrystalline, or amorphous. In one embodiment, the density of the material ranges between 5 and 7.3 g/ml.

In one embodiment, this invention provides a process for making a material of this invention, the process comprising:
adding an alkaline aqueous solution to an aqueous solution containing Ce ions, ions of metal M and optionally ions of a metal L;
keeping the resulting mixture at an elevated temperature, optionally while stirring, for a period of time of at least 25 mins; and
optionally washing the resulted precipitate.

In one embodiment, the origin of the Ce ions, the metal M ions and optionally the metal L ions is a salt of the ions. In some embodiments the metal L is a lanthanide.

In one embodiment, the salts of the ions are Ce(NO₃)₃·6H₂O, ZrO(NO₃)₂·6H₂O, and optionally L(NO₃)₃·6H₂O.

In one embodiment, the alkaline aqueous solution comprises (NH₄)₂CO₃.

In one embodiment, the step of adding an alkaline aqueous solution is conducted by drop-wise adding. In one embodiment, the resultant precipitate is a powder. According to this aspect and in one embodiment, the formed powder is ground and optionally calcined. In one embodiment, the powder undergoes pressing in a mold or die, resulting in the formation of a disk, bar or a pellet.

In one embodiment, the dimensions of the disk, bar or pellet comprise a diameter or any other lateral dimension ranging between 5-20 mm, and a thickness ranging between 0.5-5 mm.

In one embodiment, the porosity of the disk or the pellet ranges between 0.01% and 5%. In one embodiment, the porosity of the disk or the pellet is below 5%. In one embodiment, the disk, bar or the pellet is polished. In one embodiment, polishing makes the top and bottom faces of the disk or the pellet parallel.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1A-1B show plots as follows: FIG. 1A the relative dielectric constant (Er, real part); and FIG. 1B the conductivity of: Zr, Yb and 10 mol % Zr co-doped with Yb, as a function of dopant concentration measured by impedance spectroscopy. Values are taken at 100 Hz.

FIGS. 2A-2E show longitudinal electrostriction coefficient, M33, as a function of frequency of ceria doped with Zr (5, 10 and 20 mol %) (FIG. 2A); ceria doped with 10 mol % Zr and Yb (FIG. 2B); ceria doped with 10 mol % Zr with La (FIG. 2C); ceria doped with 10 mol % Zr and Yb (FIG. 2D); M33 for all compositions investigated at 100 Hz (FIG. 2E).

FIG. 3 is a graph showing saturation magnetization measurements for varying Zr doping and material oxidation states, measured at 2K; 10 mol % and 20 mol % Zr doped samples were measured before (reduced ‘Red’) state and after (oxidized ‘Ox’) states. Co-doped samples did not show a difference. M is magnetization in units of Ampere/meter (A/m); poH is the magnetic field/flux in units of Tesla.

FIGS. 4A-4B show plots as follows: FIG. 4A the change of dielectric constant (ε) with applied compressive pressure (-σ) divided by the vacuum permittivity (ε₀) measured at various frequencies; and FIG. 4B converse and direct electrostriction constant as a function of frequency. Both plots are measured for oxidized 10 mol % Zr doped ceria.

FIGS. 5A-5C show plots presenting high frequency electrostriction coefficient measured for: 10 mol % doped ceria samples (various dopants) (FIG. 5A); for Zr doped samples (FIG. 5B); and for 10 mol % Zr co-doped with Yb or with La samples (FIG. 5C) at different concentrations and oxidation states.

FIGS. 6A-6B Magnetization curves produced from FIG. 3: magnetization of the oxidized sample subtracted from the reduced ones (FIG. 6A); and magnetization of the 10 mol % Zr with 0.5 mol % of La sample subtracted from the magnetization of the reduced\oxidized samples (FIG. 6B). Fitting parameters to Langevin for each curve are presented.

FIG. 7 Lattice parameters of oxidized Ce_{(1-x-y)}ZrₓL_{y}O_{(2-y/2)} (Lis Yb or La) ceramics were calculated by linear regression based on the indexing of 10 diffraction peaks according to Fm3̅m.

FIGS. 8A-8D show SEM micrographs of the circumferential surface of ceria ceramic discs doped with: 5 mol % Zr (FIG. 8A); 10 mol % Zr (FIG. 8B); 10 mol % Zr co-doped with 0.5 mol % Yb (FIG. 8C); 10 mol % Zr co-doped with 15 mol % Yb (FIG. 8D). Scale bars indicate 1 μm.

FIG. 9 presents comparison of the longitudinal electrostriction coefficient, M33, Zr_{0.1}Ce_{0.9}O₂ with the best commercial electrostrictor PMN-PT. The electrostriction and the operational frequencies are similar but Zr_{0.1}Ce_{0.9}O₂ has >20 fold lower dielectric constant and >3 fold larger elastic modulus than PMN-PT.

FIGS. 10A-10B show plots as follows: FIG. 10A-Real component of the complex relative dielectric permittivity of sintered and re-oxidized ceria ceramics doped with Zr⁴⁺, La³⁺ or 10 mol % Zr⁴⁺ co-doped with La³⁺ measured using impedance spectroscopy under ambient conditions. FIG. 10B-Electrical conductivity, σ. The data shown for Vac=10 volts, f=100 Hz, with spring loaded electrodes. Two pellets with the same chemistry of each composition were measured in triplicate.

FIG. 11 shows Young's modulus, Y, of the La- and Yb-doped and Zr-co-doped ceria.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

In one embodiment, this invention provides doped ceria-based materials exhibiting electrostriction properties and methods of preparation thereof.

### Definitions

In embodiments of this invention, abbreviations are as follows: PMN-PT is lead magnesium niobate-lead titanate. ZrDC10=Zr-doped Ceria, doping of 10 mol %. The number 10 refers to 10 mol %. Similarly, 20 refers to 20 mol % etc. M₃₃ is the electrostriction constant.

Newnham's scaling law for classical electrostrictors is an empirical correlation between the dielectric constant, mechanical properties (Young's modulus) and their electrostriction coefficient.

In embodiments of this invention, the electrostriction coefficient |M₃₃|, is in units of m²/V². Longitudinal electrostrictive strain (i.e. parallel to the applied electric field) is designated u₃₃ in units of ppm. The subscript 33 indicates that the field and the strain are in the same direction, both perpendicular to the pellet/film surface.

In embodiments of this invention, electrostriction refers to the change of shape of the material under application of an electric field. In embodiments of this invention the ‘electrostriction strain coefficient’ is interchangeable with the ‘electrostriction coefficient’. In embodiments of this invention the electrostriction coefficient is interchangeable with M₃₃. In one embodiment, the electrostriction strain coefficient is designated as |M|, M₃₃, |M₃₃| m²/V² etc. Longitudinal electrostrictive strain (i.e., parallel to the applied electric field) is designated u₃₃.

The application of an electric field on the material of this invention can be carried out in a number of different ways. In one embodiment the ceria-based material is placed in between electrodes and a voltage is applied across the ceria-based material. In some embodiments, the ceria-based material is connected to a means of measuring impedance spectroscopy. In some embodiments, the voltage is measured as a function of frequency. The ceria-based material can be used in any form, for example: pellet, disk, bar, etc, when placed in between electrodes. The terms “voltage” and “bias” are used interchangeably, in some embodiments. In one embodiment the electrodes consist of metal. In some embodiments a voltage of 10 V is applied. In some embodiments a voltage of between 5-50V is applied. In some embodiments, the direct current is used. In some embodiments the alternating current is used. In some embodiments, the voltage/electric field is being applied to obtain electrostriction coefficient of a ceria material between 10⁻¹⁵ m²/V² and 10⁻¹⁸ m²/V².

Typically, frequency dependent measurements are required to measure impedence spectroscopy. As such, alternating voltages are typically used to determine the electrostriction coefficient, as described herein. In one embodiment the electrodes comprise at least one metal. Examples of electrode materials include, but is not limited to: aluminum, steel, stainless steel, iron, silver, gold, copper, etc. In further embodiments, the electrodes are connected to a waveform generator. This waveform generator applies a waveform of any frequency and any waveform shape. In some embodiments the frequency ranges between 150 mHz to 1 kHz. In other embodiments the frequency ranges between 1 kHz to 10 kHz. In other embodiments the frequency ranges between 50 mHz to 150 mHz. In some embodiments the frequency ranges between 0.1 Hz and 105 Hz. In some embodiments the form of the waveform is selected from any of the following: sinusoidal, square-wave, triangle, sawtooth, pulsed, or any combinations thereof. In one embodiment, one electrode is spring loaded. In some embodiments, the spring loaded electrode is connected to a means of measuring displacement. In some embodiments, the electrodes are connected to a dielectric analyzer and a force sensor.

The electrodes that are connected to the ceria-based materials are applied in a number of different ways, according to embodiments of the invention. In one embodiment, the electrodes are physically pressed onto different parts of the ceria-based material. In some embodiments, additional coupling materials are used to connect the electrodes to the ceria-based materials. For example, the electrodes can be coupled to the ceria-based material with any of the following non-limiting examples: conducting grease, conducting glue, conducting material, conducting tape, conducting gel, carbon nanowire-based tapes, clamps, clips or any combinations thereof. In some embodiments, the electrodes are deposited on the ceria-based material using known fabrication techniques.

Lanthanides are rare earth elements. In some embodiment, lanthanides are designated ‘L’ and in other embodiments ‘RE’ (rare earth). In one embodiment, ‘L’ represent lanthanide in general (e.g. of any ionic charge). In one embodiment, ‘L’ represents lanthanide of 3+ ionic charge. The designation of L is apparent from a material formula where given, as known in the art.

In embodiments of the invention, “ceria” refers to an oxide of the rare-earth metal cerium. As such, and in some embodiments “ceria-based materials” refers to materials that comprises ceria.

In embodiments of this invention, ‘single-doped ceria’ refers to ceria doped with one type of dopant. As used herein “co-doped” refers to doping by at least two different dopants. In some embodiments of this invention, “co-doped” refers to doping with one of Zr, Hf and Ti, and co-doping with a lanthanide. For example, Ce doped with Zr and with Yb is a co-doped Ce, in one embodiment.

In one embodiment, materials of this invention are referred to as active materials. In one embodiment, active material is a material that presents an electromechanical effect. In one embodiment, an active material is the material that undergoes a mechanical change as a response to an applied electric field. In one embodiment, the active material is an electrostrictive material.

In one embodiment, displacement is a change in the position of the active material or portions thereof. In one embodiment, displacement means a change of location, change of the coordinates of the active material or portions thereof. In one embodiment, displacement describes the movement of the active materials or portions thereof as a result of an applied electric field. In one embodiment, a displacement is observed as a change in length, increased or decreased curvature, bending or increase/decrease in bending, elongation, shrinkage, change in volume, change in width, or any other change in the dimensions or in the geometry of the active material or portions thereof. In one embodiment, force is exerted by the active material upon application of an electric field. In one embodiment, force is developed in the active material. In one embodiment, when the active material is under the influence of an electric field, the active material can resist an external force. In one embodiment, the active material of this invention generates a mechanical force.

In one embodiment, deformation is a change in dimensions of a material. In one embodiment, deformation is equivalent to or comprising displacement as descried herein above.

In one embodiment, strain is the amount of deformation a material experiences per unit of original length in response to stress. In one embodiment, in-plane strain is the strain within the thin film directed perpendicular to the smallest dimension of the film. In one embodiment, the in-plane strain in thin films can be described as follows: in thin film technology, due to the fact that thin films have one dimension which is much smaller than two others, most properties can be roughly divided to two classes: in-plane & out-of-plane. The in-plane parameters refer to the parameters directed perpendicular to the “thin” or to the smallest dimension of the thin film. In one embodiment, in-plane strain is the strain within the thin film or within the active material. In one embodiment, longitudinal electrostrictive strain was calculated as the ratio between the displacement and the original thickness of the ceramic pellets.

In one embodiment, elastic modulus is the ratio of stress, within the proportional limit, to the corresponding strain. In one embodiment, elasticity is the tendency of a material to return to its original shape after it has been stretched or compressed.

In one embodiment, pm represents units of picometers. In one embodiment, nm represents units of nanometers. In one embodiment, MPa represents units of Mega Pascal. In one embodiment, V represents Volts. In one embodiment, μm represents micrometers. In one embodiment, ppm represents parts-per-million.

In one embodiment, stress is the force that a material is subjected to per unit of original area. In one embodiment, stress in materials of the invention depends on voltage (bias/electric field) applied.

In some embodiments, the co-doped material is represented by Ce_{1-x-y}MₓL_{y}O_{2-y/2}. In one embodiment, x, y, 1-x-y, etc. indicates the amount/ratio of the various ions in the material where M is a cation with a charge of 4+ and L is a lanthanide with a charge of 3+. The percentage of each atom/ion in the material can be calculated for any known x, y, z, 1-x-y-z, etc.

In one embodiment, M is an isovalent metal and L is an aliovalent metal. In one embodiment, M is selected from Zr, Ti and Hf, and L is an element selected from the group of lanthanides.

In one embodiment, the active material is represented by Ce_{1-x-y-z}MₓL_{y}N₂O_{2-y/2-z-δ}. In one embodiment, x, y, z, 1-x-y-z, etc. indicates the amount/ratio of the various ions in the crystal. Where M is a cation with a charge of 4+, L is a cation with a charge of 3+, and N is a cation of charge of 2+. δ is the spontaneous reduction that depends on partial oxygen pressure, usually ˜100 ppm at standard conditions. The percentage of each atom/ion in the material can be calculated for any known x, y, z, 1-x-y-z, etc. In embodiments of this invention, either L or N or their combination can be present in materials of this invention. According to this aspect and in one embodiment, y which represents the amount of L is 0 or ranges between 0 and 0.7 and z which represents the amount of N is 0 or ranges between 0 and 0.7. In some embodiments wherein the material is a single-doped Ce (e.g. CeZrO₂), y=0 and z=0. In one embodiment, both L and N are lanthanides. In some embodiments, L and M can each independently represent a lanthanide of a certain charge that is possible for a particular lanthanide. The chemical formula can be adjusted accordingly as known in the art.

In some embodiments of this invention, since 8 is very small, it is not represented in the formula for the oxygen ions. According to this aspect and in one embodiment, the amount/ratio of the oxygen ions is stated as ‘2-y/2’ or as ‘2-y/2-z’. In such designation and in some embodiments, it is to be noted that the amount/ratio includes a deviation from the value of 0.01% or of 0.02% or a deviation ranging between 0.001% and 0.07% of the stated or calculated value. Such deviation accounts for the small amount of reduced positive ions if present and the corresponding variation (if any) in the amount of oxygen ions. According to this aspect and in one embodiment, the value of 8 is 0.0001 or is 0.0002 or 8 ranges between 0.00001 and 0.0007.

In one embodiment, metal ion is referred to in short as ‘metal’. In some embodiments, the terms constant and coefficient are interchangeable. In one embodiment, when referred to displacement, deformation or strain, one part per million (ppm) may describe a change of 1 micrometer per meter of original/initial dimension.

### Materials, Dimensions and Values

In one embodiment, this invention provides a ceria-based material, doped by a metal M, wherein the metal M is selected from Hf, Zr and Ti, wherein upon application of an electric field the ceria-based material generates displacement, stress or a combination thereof. In one embodiment the application of an electric field only generates displacement. In another embodiment the application of an electric field only generates stress.

In one embodiment, this invention provides a ceria-based material, doped by a metal M, said metal M is selected from Hf, Zr and Ti, wherein said material is electrostrictive.

In one embodiment, this invention provides a ceria-based material, doped by Zr, wherein upon application of an electric field said ceria-based material generates displacement, generates stress or a combination thereof.

In one embodiment, this invention provides a ceria-based material, doped by Zr, wherein said material is electrostrictive.

In one embodiment, the material is represented by the formula Ce₁₋ₓMₓO₂ wherein x ranges between 0.02 and 0.7. In one embodiment, x ranges between 0.02 and 0.45. In one embodiment, x ranges between 0.05 and 0.3, or between 0.02 and 0.20, or between 0.08 and 0.12. In one embodiment, x is 0.1±0.01 or 0.1±0.5 or 0.2±0.5 or 0.05±0.01.

In one embodiment, the material is represented by the formula Ce₁₋ₓMₓO_{2-d} wherein ‘d’ represents the spontaneous reduction of the material. In one embodiment ‘d’ and ‘8’ are used interchangeably. In some embodiments, x ranges between 0.02 and 0.45. In one embodiment, x ranges between 0.05 and 0.3, or between 0.02 and 0.20, or between 0.08 and 0.12. In one embodiment, x is 0.1±0.01 or 0.1±0.5 or 0.2±0.5 or 0.05±0.01. In one embodiment d ranges between 0<d<0.03. In another embodiment d ranges between 0<d <0.01. In one embodiment d ranges between 0<d<0.02. In one embodiment d ranges between 0.01<d<0.02. In one embodiment d ranges between 0.02<d<0.03. In one embodiment d is about 0.01. In one embodiment d about 0.02. In one embodiment d is about 0.03.

In one embodiment the material is co-doped with a metal with a lower valence than metal M. In another embodiment the lower valence metal is selected from: Ca, Mg, Fe, Sc, Sn and Y or combinations thereof. In one embodiment the co-doped material comprises Ca, Mg, Fe, Se, Sn or Y. In one embodiment the co-doped material consists of Ca, Mg, Fe, Se, Sn or Y. As used herein “valence” (or “valency) refers to the property of an element that determines the number of other atoms with which an atom of the element can combine.

In one embodiment, the material is co-doped with a lanthanide L.

In one embodiment, the lanthanide L is any lanthanide selected from La, Pr, Nd, Pm, Sm, Eu, Gd, Tb, Dy, Ho, Er, Tm, Yb and Lu or any combination thereof.

In one embodiment, L is an ion with a 3+ charge. In some embodiments, L has a 2+ or 4+ charge.

In one embodiment, the ceria-based material is represented by the formula Ce_{1-x-y} MₓL_{y}O_{2-y/2}. In one embodiment the ceria-based material is represented by the formula Ce_{1-x-y} MₓL_{y}O_{2-y/2} wherein x ranges between 0.01-0.7 and y ranges between 0.01-0.7. In one embodiment, x, y or a combination thereof range between 0.02 and 0.45. In one embodiment, x, y or a combination thereof ranges between 0.05 and 0.3, or between 0.02 and 0.20, or between 0.08 and 0.12. In one embodiment, x, y or a combination thereof is 0.1±0.01 or 0.1±0.5 or 0.2±0.5 or 0.05±0.01.

In one embodiment, the ceria-based material is represented by the formula Ce_{1-x-y} MₓL_{y}O_{2-y/2-d}. In one embodiment the ceria-based material is represented by the formula Ce_{1-x-y} MₓL_{y}O_{2-y/2-d} wherein x ranges between 0.01-0.7 and y ranges between 0.01-0.7. In one embodiment, x, y or a combination thereof range between 0.02 and 0.45. In one embodiment, x, y or a combination thereof ranges between 0.05 and 0.3, or between 0.02 and 0.20, or between 0.08 and 0.12. In one embodiment, x, y or a combination thereof is 0.1±0.01 or 0.1±0.5 or 0.2±0.5 or 0.05±0.01. In one embodiment d ranges between 0<d<0.03. In another embodiment d ranges between 0<d<0.01. In one embodiment d ranges between 0<d<0.02. In one embodiment d ranges between 0.01<d<0.02. In one embodiment d ranges between 0.02<d<0.03. In one embodiment d about 0.01. In one embodiment d about 0.02. In one embodiment d about 0.03.

In one embodiment, the lanthanide L is La or Yb.

In one embodiment, M is Zr, L is Yb, x=0.10±0.02 and y=0.10±0.02. In one embodiment, M is Zr, L is La, x=0.10±0.02 and y=0.03±0.01. In one embodiment, M is Zr with x ranging between 0.001 and 0.2, and L is Yb with y ranging between 0.005 and 0.25. In one embodiment, M is Zr with x ranging between 0.001 and 0.2, and L is La with y ranging between 0.005 and 0.25. In one embodiment, L is La, x=0.10±0.02 and y ranges between 0.01 and 0.08. In one embodiment, L is Yb, x=0.10±0.02 and y ranges between 0.05 and 0.15.

In one embodiment, the displacement ranges between 0.1 ppm and 500 ppm. In one embodiment, the stress generated by said ceria-based material is at least 0.01 MPa. In one embodiment, the Young's modulus ranges between 100 GPa and 250 GPa. In one embodiment, the Young's modulus ranges between 190 GPa and 250 GPa. In one embodiment, the Young's modulus ranges between 200 GPa and 250 GPa.

In one embodiment, the electrostriction coefficient of the material ranges between 10⁻¹⁵ m²/V² and 10⁻¹⁸ m²/V². In one embodiment, the electrostriction coefficient of the material ranges between 10⁻¹⁵ m²/V² and 10⁻¹⁷ m²/V² or between 10⁻¹⁶ m²/V² and 10⁻¹⁸ m²/V² or between 10⁻¹⁶ m²/V² and 10⁻¹⁷ m²/V². In one embodiment, the electrostriction coefficient of the material ranges between 10⁻¹⁵ m²/V² and 10⁻¹⁸ m²/V² at a frequency ranging between 0.1 Hz and 105 Hz. In one embodiment, the electrostriction coefficient of the material ranges between 10⁻¹⁵ m²/V² and 10⁻¹⁸ m²/V² at a frequency ranging between 0.1 Hz and 10³ Hz or between 0.1 Hz and 4×10³ Hz, or between 0.1 Hz and 100 Hz. In one embodiment, the electrostriction coefficient is frequency independent. In one embodiment, the electrostriction coefficient is frequency independent at a certain frequency range.

In one embodiment, the dielectric constant of the material ranges between 10 and 1000. In one embodiment, the dielectric constant of said material ranges between 100 and 500 or between 20 and 50 or between 20 and 400 or between 100 and 200.

In one embodiment, the electrical conductivity of the material ranges between 10⁻⁹ S/m and 10⁻⁵ S/m. In one embodiment, the electrical conductivity of the material ranges between 10⁻⁹ S/m and 10⁻⁸ S/m.

In one embodiment, strain in materials of this invention ranges between 50 ppm and 500 ppm. In one embodiment, strain in materials of this invention ranges between 50 ppm and 150 ppm. In one embodiment, strain in materials of this invention is up to 200 ppm.

In one embodiment, the concentration of reduced Ce ions (Ce³⁺) ions in Ce doped or co-doped materials of this invention ranges between 50 ppm and 750 ppm or between 50 ppm and 250 ppm or between 50 ppm and 150 ppm. In one embodiment, the concentration of reduced Ce ions is about 100 ppm. In one embodiment, the concentration of reduced Ce ions is about 500 ppm.

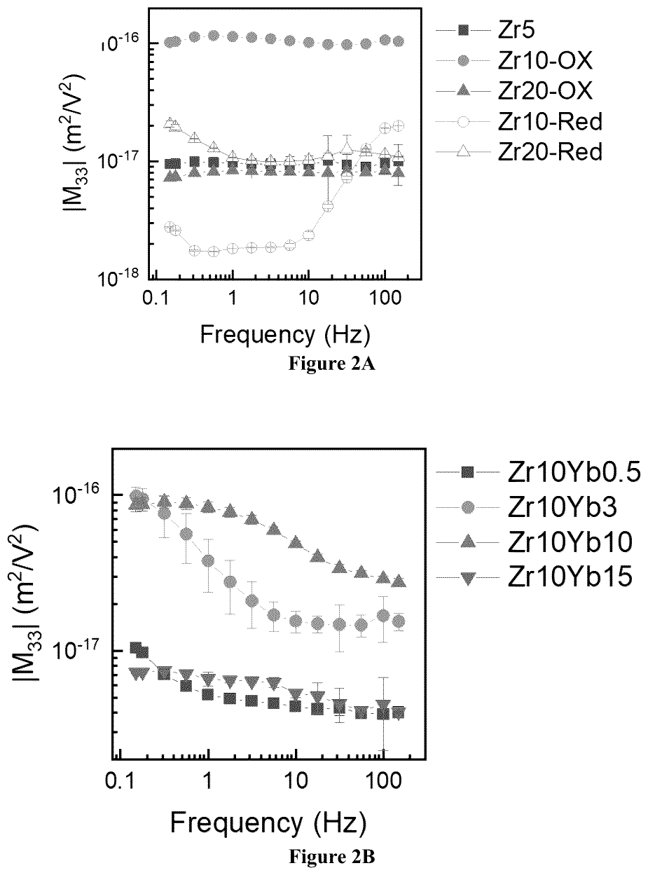

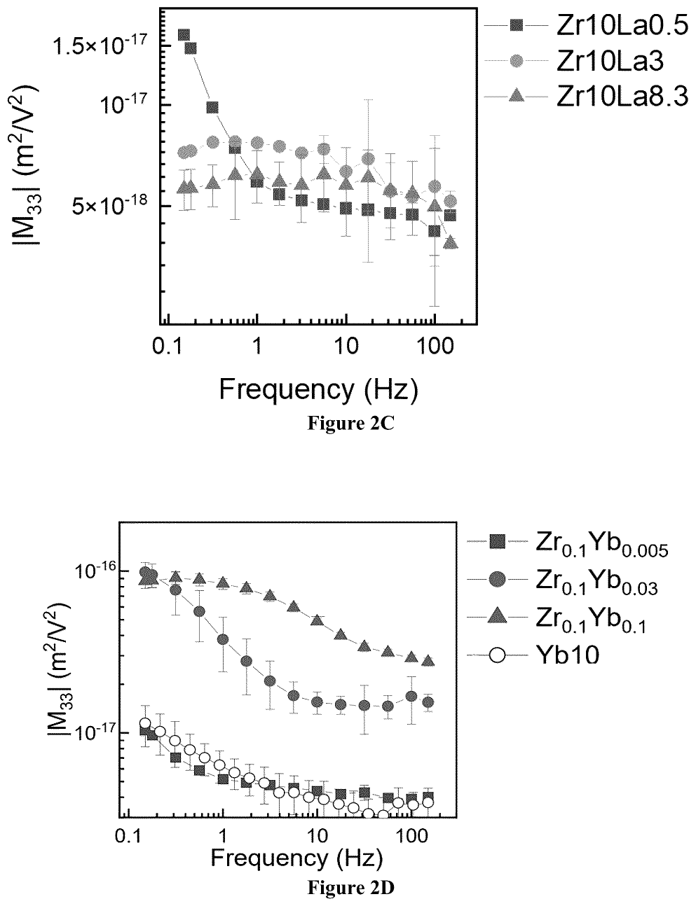

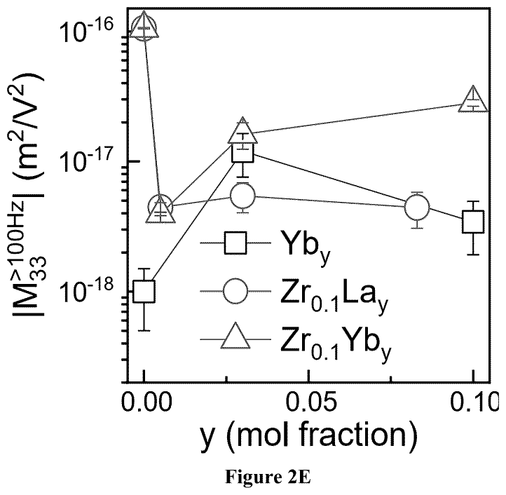

In some embodiments, the reduction (=oxygen loss) of Zr_{0.1}Ce_{0.9}O₂ or co-doping with just 0.5 mol % of La or Yb in Zr_{0.1}Ce_{0.9}O₂ (Zr:La or Zr:Yb=20:1) introduces 0.5%/4=1250 ppm of oxygen vacancies. This is sufficient to decrease the longitudinal electrostriction coefficient M₃₃, by more than an order of magnitude (FIGS. 2C, 2D and 2E). The effect of La and Yb is identical despite the large difference in their crystal radii, indicating that that the factor suppressing the electrostriction effect is the presence of oxygen vacancies. Vo, and 1250 ppm of them is enough to have a major effect on 10 mol % of Zr-dopant.

In one embodiment, the material form is a disk, a film, a powder, a bar a pellet. In one embodiment, the thickness of the disk, the film, bar or the pellet, ranges between 0.1 mm and 10 mm. Other forms are produced with materials of this invention, using molds, dies, presses, vessels, containers, rings, and other conventional tools as known in the art.

In one embodiment, the material is a single crystal or polycrystalline. In one embodiment, the material is an amorphous material. In one embodiment, the density of the material ranges between 5 and 7.3 g/ml. In one embodiment, the density of the material ranges between 7 and 7.7 g/ml or between 5 and 7 g/ml.

Embodiments of this invention related to ceria-based materials are also applicable to Thorium (Th) based materials. According to this aspect and in one embodiment, the formula of doped materials of this invention is Th₁₋ₓMₓO₂, and the formula of co-doped materials is Th_{1-x-y}MₓL_{y}O_{2-y/2} or Th_{1-x-y-z}MₓL_{y}N₂O_{2-y/2-z} for materials co-doped by ions with 4+, 3+ and 2+ charge, or Th_{1-x-y-z}MₓN_{y}L₂O_{2-y/2-z-δ} for co-doped materials wherein the amount of reduced ions is accounted for by δ. Some embodiments disclosed herein for Ce are relevant to materials where Th replaces Ce. Such Th-related embodiments are included in this invention.

Provided herein actuators, sensors, and transducers comprising the ceria-based material provided herein. In some embodiments provided herein an actuator comprising the ceria-based material provided herein. In an embodiment the actuator comprises at least one layer of the ceria-based material. In some embodiments provided herein a sensor comprising the ceria-based material provided herein. In some embodiments provided herein a transducer comprising the ceria-based material provided herein.

### Methods of Production of Materials of the Invention

In one embodiment, this invention provides a process for making a material of this invention, the process comprising:
adding an alkaline aqueous solution to an aqueous solution containing Ce ions, ions of metal M and optionally ions of a metal L;
keeping the resulting mixture at an elevated temperature, optionally while stirring, for a period of time of at least 25 mins; and
optionally washing the resulted precipitate.

In one embodiment, this invention provides a process for making a material of this invention, the process comprising:
adding an alkaline aqueous solution to an aqueous solution containing Ce ions, ions of metal M and optionally ions of a metal L;
keeping the resulting mixture at an elevated temperature, for a period of time of at least 25 mins; and
optionally washing the resulted precipitate.

In one embodiment the elevated temperature is any temperature above room temperature. In another embodiment the elevated temperature ranges between 30 to 50° C. In another embodiment the elevated temperature ranges between 50 to 70° C. In another embodiment the elevated temperature ranges between 70 to 100° C. In another embodiment the elevated temperature ranges between 100 to 200° C.

In one embodiment the period of time for keeping the resulting mixture at an elevated temperature, optionally while stirring, ranges between 25 mins to 1 hr. In one embodiment the period of time for keeping the resulting mixture at an elevated temperature, optionally while stirring, ranges between 1 to 2 hrs. In one embodiment the period of time for keeping the resulting mixture at an elevated temperature, optionally while stirring, ranges between 2 to 5 hrs. In one embodiment the period of time for keeping the resulting mixture at an elevated temperature, optionally while stirring, is about 25 mins.

In one embodiment, the origin of the Ce ions, the metal M ions and optionally the metal L ions is a salt of said ions. In some embodiments the metal L is a lanthanide. In some embodiments the metal L comprises at least one lanthanide.

In one embodiment, the salts of said ions are Ce(NO₃)₃·6H₂O, ZrO(NO₃)₂·6H₂O, and optionally L(NO₃)₃·6H₂O.

In one embodiment, the alkaline aqueous solution comprises (NH₄)₂CO₃. In one embodiment, the alkaline aqueous solution comprises a carbonate. In one embodiment, the alkaline aqueous solution comprises hydroxide.

In one embodiment, the step of adding an alkaline aqueous solution is conducted by drop-wise adding. As used herein “drop-wise adding” refers to the addition of liquid drops, in some embodiments. In some embodiments, drop-wise adding is carried out by a pipette. In some embodiments the drop-wise adding is automated.

In one embodiment, the resultant precipitate is a powder, and the formed powder is ground. In a further embodiment the formed powder is optionally calcined. In one embodiment, the resultant precipitate powder is not ground. In one embodiment, the resultant precipitate powder is ground but not calcined. In one embodiment, the resultant precipitate powder is ground and calcined.

### Pellets of the Invention

In one embodiment, the powder formed by methods of this invention undergoes pressing in a mold or a die, resulting in the formation of a disk, bar or a pellet. In some embodiments, the terms ‘pellet’, ‘disk’ and ‘bar’ are used interchangeably.

In one embodiment, the dimensions of the disk, bar or pellet comprise a diameter or any other lateral dimension ranging between 5-20 mm, and a thickness ranging between 0.5-5 mm.

In one embodiment, the thickness of the pellet/disk ranges between 500 nm and 1000 nm. In one embodiment, the thickness of the pellet/disk is 500 nm. In one embodiment, the thickness of the pellet/disk ranges between 500 nm and 750 nm, or between 750 nm and 1000 nm, or between 100 nm and 1000 nm, or between 500 nm and 2000 nm, or between 400 nm and 4000 nm, or between 600 nm and 800 nm, or between 1000 nm and 10,000 nm. In one embodiment, the thickness of the pellet/disk ranges between 10,000 nm and 100,000 nm.

In one embodiment, the length and width of the disk/pellet are equal. In one embodiment, the length of the material is larger than the width of the material. In one embodiment, the length and the width of the material are larger than the thickness (height) of the material. In one embodiment, the length of the material is four centimeters and the width of the material is 0.8 cm. In one embodiment, the material is circular with a diameter ranging between 0.2 cm and 7 cm. In one embodiment, the material has an oval shape with diameters ranging between 0.2 cm and 7 cm.

In one embodiment, the length of the material, the width of the material or a combination thereof ranges between 0.5 cm and 5 cm. In one embodiment, the length of the material, the width of the material or a combination thereof ranges between 0.1 cm and 1 cm. In one embodiment, the length of the active material, the width of the active material or a combination thereof ranges between 1 cm and 10 cm, or between 10 cm and 100 cm, or between 0.01 cm and 0.1 cm, or between 10 micrometer and 100 micrometers, or between 1 micrometer and 10 micrometers. In one embodiment, the active material is in the form of a disc. In one embodiment, the diameter of the disc may comprise any value as described herein above for the width/length of square/rectangular active materials. In one embodiment, the thickness of the disc is any value described herein above for the thickness of the active material. In one embodiment, the active material may comprise any geometrical shape, or it can be of an undefined or partially defined geometry. In cases where the geometry of the active material is not well-defined, the values described herein above for length/width and thickness may represent the largest and/or smallest dimensions of the active material. In one embodiment, ‘active material’ refers to material and vice versa. In one embodiment, dimensions and values cited for materials of this invention refer to pellets/disks/films of this invention. Disk and disc are interchangeable in embodiments of this invention and refer to a thin and cylindrical (or close to cylindrical) object or geometry.

In one embodiment, the porosity of the disk, bar or pellet ranges between 0.05% and 5%. In one embodiment, the porosity of the disk, bar or pellet ranges between 0.01% and 5%. In one embodiment, the porosity of the disk, bar or pellet ranges between 0.15% and 0.25%. In some embodiments, porosity of materials of this invention is less than 2%. In some embodiments, porosity of materials of this invention is less than 5%.

In one embodiment, the disk, bar or the pellet is polished. In one embodiment, the top and/or the bottom face(s) of the disk or the pellet are made parallel. In one embodiment, the top and/or the bottom face(s) of the disk or the pellet are made parallel by polishing.

In one embodiment, the term “a” or “one” or “an” refers to at least one. In one embodiment the phrase “two or more” may be of any denomination, which will suit a particular purpose. In one embodiment, “about” or “approximately” may comprise a deviance from the indicated term of ±1%, or in some embodiments, −1%, or in some embodiments, ±2.5%, or in some embodiments, ±5%, or in some embodiments, ±7.5%, or in some embodiments, ±10%, or in some embodiments, ±15%, or in some embodiments, ±20%, or in some embodiments, ±25%.

The following examples are presented in order to more fully illustrate the preferred embodiments of the invention. They should in no way be construed, however, as limiting the broad scope of the invention.

### EXAMPLES

### Example 1

### Sample Preparation and Characterization

### Sample Preparation.

Solid solutions ZrₓRE_{y}Ce_{1-x-y}O_{2-y/2}, with RE=La or Yb were synthesized via rapid sintering. In brief, an aqueous solution of (NH₄)₂CO₃ (Acros Organics, extra pure, 99%) was added drop-wise to an aqueous solution containing Ce(NO₃)₃·6H₂O (Strem 99.9% purity). Doped ceria was prepared by co-precipitating cerium nitrate with ZrO(NO₃)₂·6H₂O. Co-doped ceria was prepared by co-precipitating cerium nitrate with the appropriate RE(NO₃)₃·6H₂O (Strem 99.9% purity) and ZrO(NO₃)₂·6H₂O. The resulting mixture was kept at 80° C. under continuous stirring for 1 hour. Precipitates were washed with deionized water and then ethanol, and the powder was ground and calcined. Flat disks with 11 mm diameter and 2 mm thick were made by cold isostatic pressing (300 MPa) in a polyurethane mold. The porosity of all sintered pellets was deduced from the mass density measured by the conventional Archimedes technique. Pellets were polished and top and bottom faces were made parallel with silicon carbide polishing papers (up to 1600 mesh). Silicon carbide residue was removed by 30 min washing with 100% ethanol in an ultrasonic bath. Where specified, all samples were heated at 500° C. for 5 h in pure oxygen atmosphere to compensate for possible oxygen loss during sintering.

### Electrostrictive Strain.

Longitudinal (i.e., parallel to the applied electric field) electrostrictive strain, u₃₃, was measured with instrumentation described previously. Briefly, the ceramic pellet was inserted between two stainless steel electrodes, the top electrode being spring loaded. Voltage was applied using a Keithley 3390 waveform generator, and a Trek 610E amplifier. A pushrod was used to transfer displacement from the electrodes to a proximity sensor (Capacitance, CPL190 Lion); the signal from the proximity sensor was read with a lock-in amplifier (DSP 7265). Longitudinal electrostrictive strain is calculated as the ratio between the displacement and the original thickness of the ceramic pellets as measured with a Mitutoyo (193-111, ±2 μm) screw gauge. Measurements were performed under ambient conditions (24±2° C., relative humidity 20%-55%). Commercial samples of Pb(Mg_{1/3}Nb_{2/3})O₃—PbTiO₃ (PMN-PT) with silver metal contacts (TRS Technologies) and a 100-cut quartz single crystal without additional sputtered metal contacts were used for calibration of the measurement setup. Electromechanical values matching literature data were obtained: electrostriction of PMN-PT M₃₃=(1.5±0.5)·10⁻¹⁶ m²/V², and piezo coefficient of quartz crystal d₃₃=2.3±0.2 pm/V. Measurements were done within the frequency range 150 mHz-1 kHz.

### Impedance Spectroscopy and Converse Electrostriction.

Room temperature impedance spectroscopy measurements were conducted with a Novocontrol Alfa dielectric analyzer in high voltage mode. Applied voltages were: 10 VAC, 1 MHz-1 mHz; 0 VDC. Measured impedance values fall within the 1% accuracy range of the impedance analyzer.

Electrostriction can also be defined as:

$$M = {ε}_{0} \frac{\partial {ε}_{r}}{\partial σ} \qquad ( 1 )$$

where Er is the real part of the relative dielectric constant, measured using impedance spectroscopy. σ is the stress applied to the sample (using a vise), calculated using a force sensor and sample dimensions. Measuring the change in dielectric constant with varying pressures can be used to inversely measure electrostriction constant:

$${ε}_{r} = M \frac{σ}{{ε}_{0}} + {ε}_{r} {\vert}_{σ = 0} \qquad ( 2 )$$

### Superconducting Quantum Interference Device (SQUID).

Temperature-dependent magnetization of the ceramic pellets was measured using a SQUID (superconducting quantum interference device) magnetometer MPMS3 (LOT-Quantum Design Inc.) in the VSM (vibrating sample magnetometry) mode. The rod-shaped samples were mounted on quartz plates with poly(vinyl alcohol) glue, such that the long axis of a rod was aligned with the long axis of the quartz plate. Magnetization (M) values (A·m⁻¹) were normalized using the rod density calculated from the lattice parameter. Dependence of magnetization on temperature in constant magnetic field (μ₀H=0.5 T) was measured in the range of 5K≤T≤300 K. Both zero field cooled (ZFC) and field cooled (FC) modes were applied, with no observable difference between them.

The magnetic saturation (M) plots were fitted to a Langevin curve:

$$M = Ng {μ}_{B} J \cdot L ( η ) + {χ}_{0} \cdot H \qquad ( 3 )$$

where N is the number of magnetic species per unit volume (m⁻³); g is the Landé g-factor; μ_{B} is the Bohr magneton; J=|L±S|. The Langevin function is

$$L ( η ) = coth ( η ) - \frac{1}{η} , \qquad ( 4 )$$

where η is the ratio of the magnetic to thermal energy,

$$η = \frac{g {μ}_{0} {μ}_{B} J}{{k}_{B} T} \cdot H ;$$

μ₀ is the vacuum magnetic permeability; k_{B} is the Boltzmann constant; T is the absolute temperature (K); and H is the magnetic field strength (A/m).

The magnetic susceptibility (x) plots were fitted to a Curie-Weiss law:

$$χ ( T ) = \frac{C}{T - {T}_{C}} + {ξ}_{0} \qquad ( 5 )$$

where C and Tc are the Curie constant and Curie temperature, respectively. X₀ is a temperature independent contribution which accounts for diamagnetic and Van Vleck susceptibility.

### Results

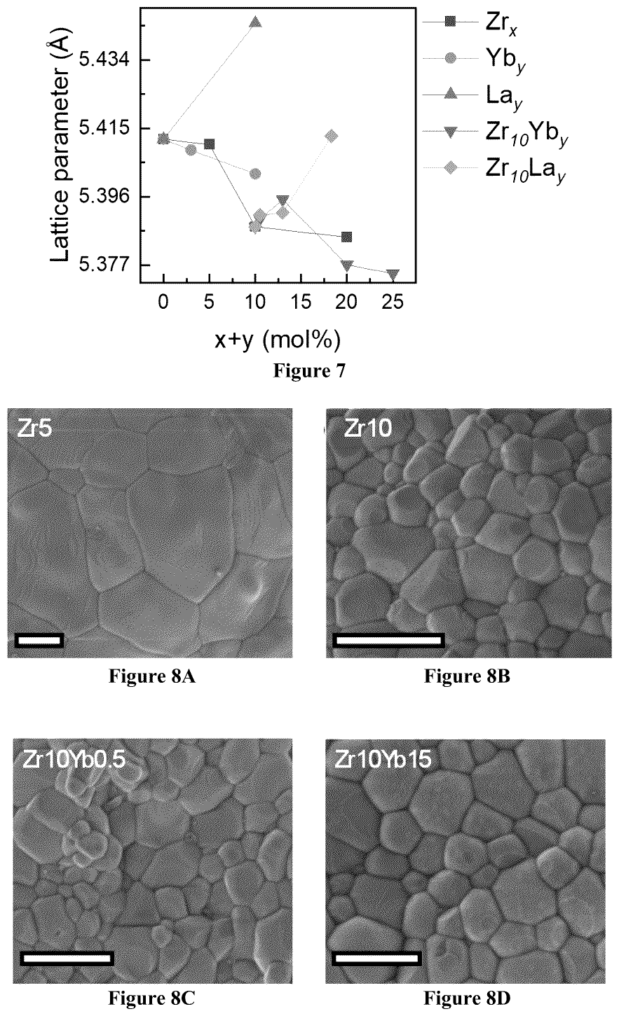

X-ray diffraction patterns of the ceria solid solution ceramic pellets, doped with varying concentrations of aliovalent (Yb and La) and isovalent (Zr) ions, can be indexed as an untextured cubic fluorite polycrystal (Fm3̅m,). The lattice parameter decreased for Zr and Yb doping and increased with La doping. The change in lattice parameter was linear with dopant concentrations (FIG. 7). SEM (Zeiss Sigma 500) images of pellet circumferential surfaces revealed that the grain sizes, as estimated by the lineal intercept method are around 500 nm (FIG. 8A-FIG. 8D). All samples show very low porosity (<2%). The Young's modulus measured by USTOF (ultra-sound time of flight) of all Zr doped samples is ˜200 GPa, while co-doping lowers the modulus to 200 GPa. Sintered pellets of Zr doped ceria were reduced (greenish-black color) and were oxidized after sintering by heating them in an oxygen environment for 5 hours in 500° C. (color change to yellow-white). While reduced vs. the oxidized Zr-doped samples showed difference in their electrostriction coefficient, Other pellets (co-doped) showed no change in any measured parameter before and after sintering.

### Electrical Impedance

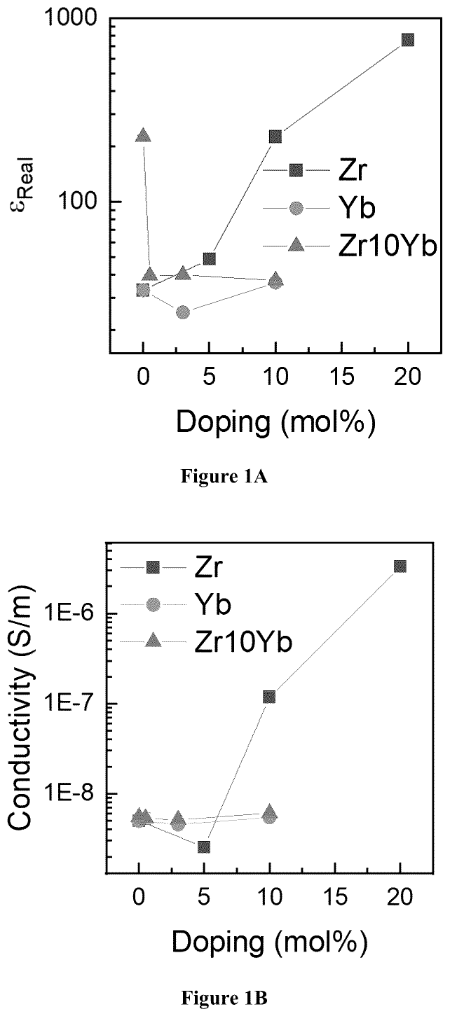

Doping ceria with Zr increased the dielectric constant (Er, real part) by several orders of magnitude compared to undoped ceria (εᵣ˜33), FIG. 1A. An increase of one or more orders of magnitude was also observed in conductivity (FIG. 1B). Co-doping with an aliovalent cation (e.g. Yb or La) returned conductivity and dielectric constant to much lower values. The dielectric values of undoped ceria, and aliovalent doped ceria were close to those predicted by Clausius-Mossoti (see Choy, T. C. (2015) Effective medium theory: principles and applications (Vol. 165). Oxford University Press. P. 5-9). No large changes in dielectric constant/conductivity were observed between oxidized and reduced pellets of Zr doped ceria; i.e. between before and after oxidation (500° C. for 5 h in pure oxygen) of the pellets of Zr-doped ceria (10 mol % and 20 mol %). Values in FIGS. 1A-1B were for oxidized pellets (see also above reduced vs. oxidized, sintered vs. sintered in an oxygen atmosphere).

### Electrostriction

The electrostriction values of Zr doped ceria were highly dependent on the oxidation state of the pellets. Reduced pellets displayed much lower electrostriction values than oxidized ones (FIG. 2A). The electrostriction constant of oxidized samples showed no major dependence on frequency. In addition, co-doping the 10 mol % Zr with Yb or La showed no major difference before and after oxidation treatment, and no clear dependence on frequency (FIG. 2B). Co-doping Zr with Yb (FIG. 2B) or La (FIG. 2C) reduced the electrostriction constant and in some samples induces relaxation (decrease of electrostriction coefficient with frequency).

### SQUID

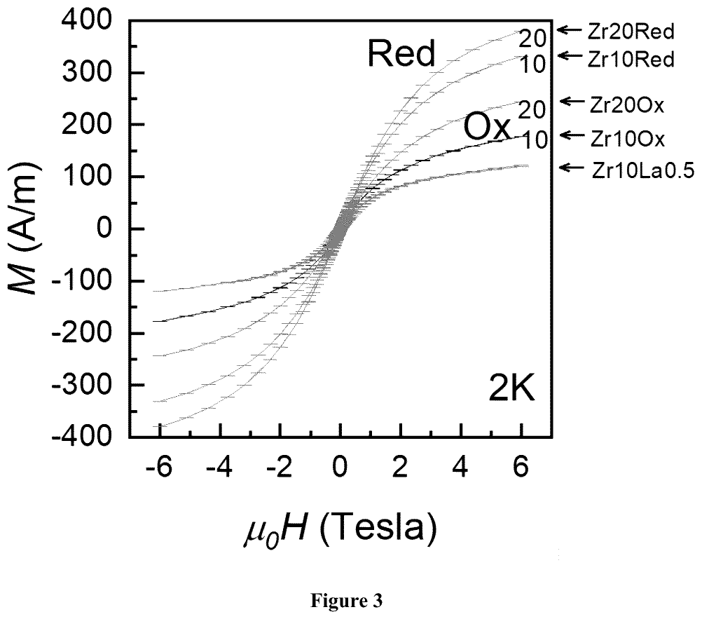

The saturation magnetization at 2K (FIG. 3) increased with increasing Zr doping. In addition, the oxidized samples saturated at much lower values than the reduced ones. In embodiments of this invention, magnetization results were used for measuring Ce³⁺ concentration.

### Converse Electrostriction

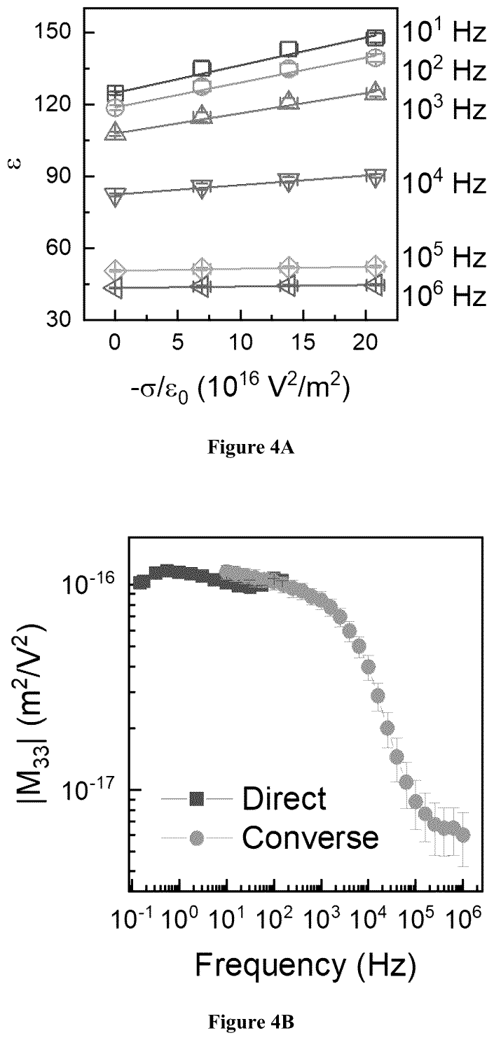

Applying compressive stress to an oxidized pellet of 10 mol % Zr doped ceria increased the dielectric constant (FIG. 4A). Using the slope, electrostriction coefficient is calculated (eq. 2, see herein above), which is in good agreement with the direct electrostriction coefficient (FIG. 4B).

### DISCUSSION

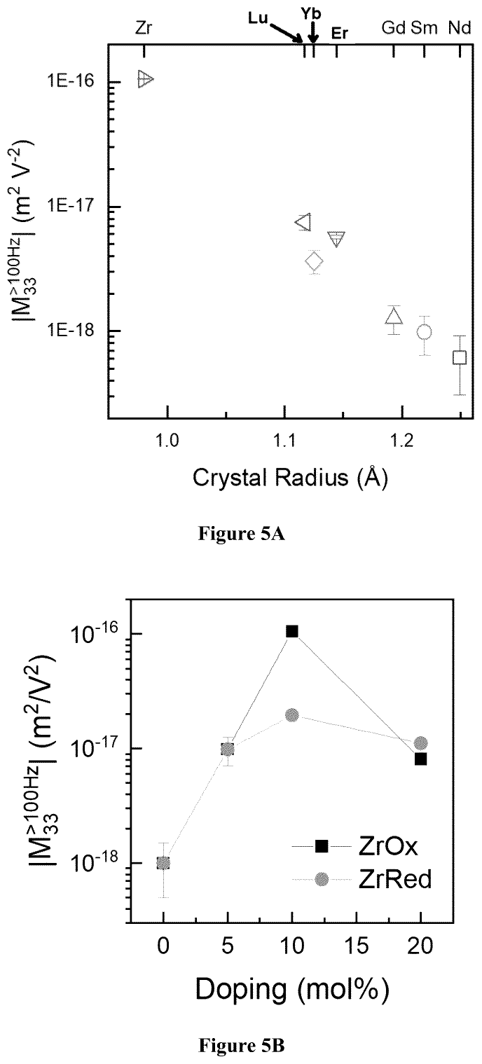

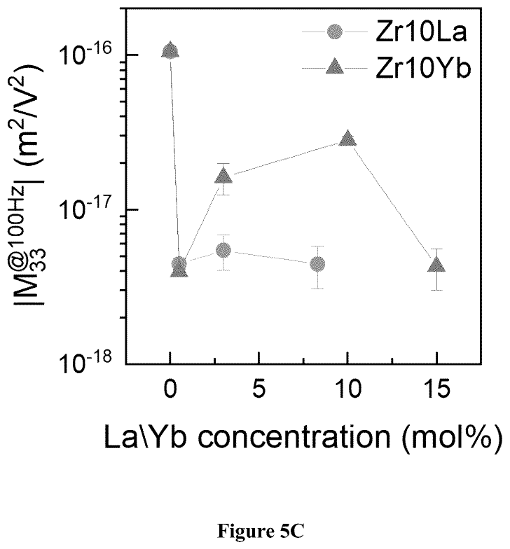

It was observed that the high frequency electrostriction coefficient of doped ceria increased with decreasing ionic crystal radius (FIG. 5A). This was explored with lanthanides, where 10 mol % Lu doped samples showed nearly 10⁻¹⁷ m²/V². However, Lu is too expensive to be used commercially and no smaller ionic-radius lanthanides exist. However, it was found in this invention that ceria can be easily doped with other non-lanthanide ions such as Zr (0.98 Å). Doping ceria with 10 mol % Zr indeed produces a very high electrostriction coefficient of 10⁻¹⁶ m²/V². Without being bound to any theory, this result shows that for single doped ceria, at a constant dopant concentration, the most important factor determining the magnitude of the electrostriction coefficient is dopant size. This coefficient is frequency independent (0.15-3000 Hz) and has no strain saturation (i.e. strain remains proportional to the field squared). Strains of 200 ppm were reached at 1 MV/m. This high coefficient is only achieved after samples were oxidized (500° C. for 5h, at pure oxygen environment) and only at 10 mol % of Zr (FIG. 4B). Oxidation state remains stable.

Higher or lower concentration of Zr show a much smaller coefficient (FIG. 5B) after oxidation, while the electrostriction coefficient of the reduced samples does not change significantly with the concentration of Zr. Co-doping 10 mol % Zr samples (FIG. 5C) with either Yb or La decrease the electrostriction coefficient at low doping, but further doping with Yb shows an optimal co-doping of 10 mol %.

The behavior of the ceramics with higher concentration of La and Yb: Zr_{0.1}REₓCe_{0.8-x}O_{1.9-x/2} (x<0.1, RE=La or Yb, FIGS. 2B-2D). Above 0.5 mol %, the effect of La and Yb is profoundly different. While incorporation of La to Zr_{0.1}Ce_{0.9}O₂ does not increase electrostriction, adding Yb has a mixed effect: after drop at 0.5 mol % of Yb, M₃₃ increases by a factor of 2.5 between 0.5% and 5 mol % of Yb and then by another 75% for 10 mol % of Yb. To separate the effect of Zr and Yb on the electrostriction, the M₃₃ was measured for ceramics containing only Yb: (x=0.05 and 0.1). For Y_{0.05}Ce_{0.95}O_{1.975}, M33 is close to that of Zr_{0.1} Yb_{0.05}Ce_{0.85}O_{1.975}, adding 10 mol % of ZrO₂ to Y_{0.1}Ce_{0.9}O_{1.9} increases electrostriction by an order of magnitude but it remained below that of Zr_{0.1}Ce_{0.9}O₂ (FIG. 2E). For all samples the strain vs field squared dependence remains linear till the highest field applied of E=13.7 kV/cm, indicating that for all samples this value is far below saturation field. Thus, co-doping with La does not show a pronounced dependance on concentration.

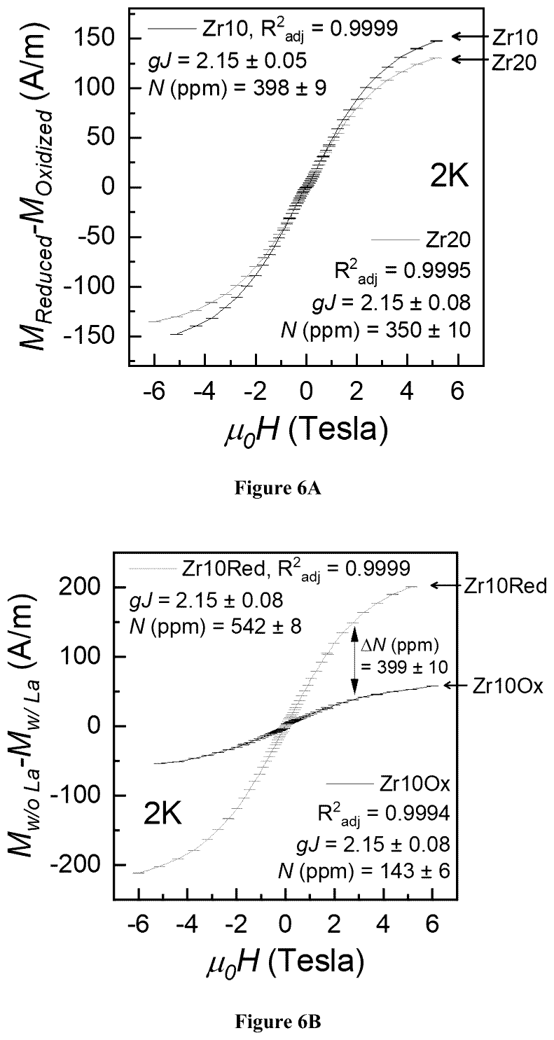

The higher conductivity values of reduced Zr can be explained by the presence of Ce³⁺ ions due to their higher tendency for reduction in the presence of Zr. The concentration of Ce³⁺ ions can be calculated from magnetization measurements. The curves in FIG. 3 cannot be fit by Langevin curves within reasonable parameters, probably because the concentration of magnetic impurities is on the order of the concentration of Ce³⁺, also ˜100 ppm. However, subtracting the oxidized curve from the reduced curve for each Zr concentration (FIG. 6A) or the oxidized\reduced curve from a sample doped with a small amount of La (FIG. 6B) produces curves which can be fit to a Langevin curve. This fitting calculates with a very high statistical certainty that the concentration of Ce³⁺ ions in the reduced Zr samples is around 500 ppm and oxidation brings them to ˜100 ppm, their concentration in undoped or aliovalent doped ceria.

Although the dielectric constant increases because of Zr doping, these electrostriction values are still much higher than predicted by Newnham's scaling law. These results suggest that elastic dipoles induced in ceria ceramics by small dopants, give stronger electrostrictive response at high frequencies (>1 Hz) than the larger dopants. For the case of isovalent doping with Zr of reduced ceria, the presence of Ce³⁺ seems to be essential for large electrostriction constant, as an optimum with Zr concentration was observed around 10 mol % (see FIG. 5B). An optional mechanism of local polarization due to reduction near the Zr atom is herein suggested. Reduction of Ce⁴⁺ into Ce³⁺ distorts the cubic position due to the formation of vacancy, creating a polaron. The creation of the polaron also explains the increase in the dielectric constant. Assuming that the concentration of these elastic dipoles is similar to that of the Ce³⁺, Clausius-Mossoti gives a polarizability of ˜8000·10⁻²⁴ cm³, a very high value not even observed in conjugated polymers.

Noting that Ce³⁺ is almost as large as La³⁺, it may be concluded that the elastic dipoles operating in Zr-doped, reduced ceria are fundamentally different from those observed for aliovalent doping.

TABLE 1
Example-comparison of some material properties

| | | | ZrDC10 + | ZrDC10 + | |
|---|---|---|---|---|---|
| | PMN-PT | ZrDC10 | Yb10 | La10 | CeO₂ |
| Dielectric | ~10,000 | 500 | 30 | 30 | 30 |
| Constant | | | | | |
| (RT@1 kHz) | | | | | |
| Young's | 100 | 200 | 200 | 200 | 220 |
| Modulus (GPa) | | | | | |
| M₃₃ (10⁻¹⁶ m²/V²) | ~1 | 1 | 0.3 | 0.04 | 0.01 |

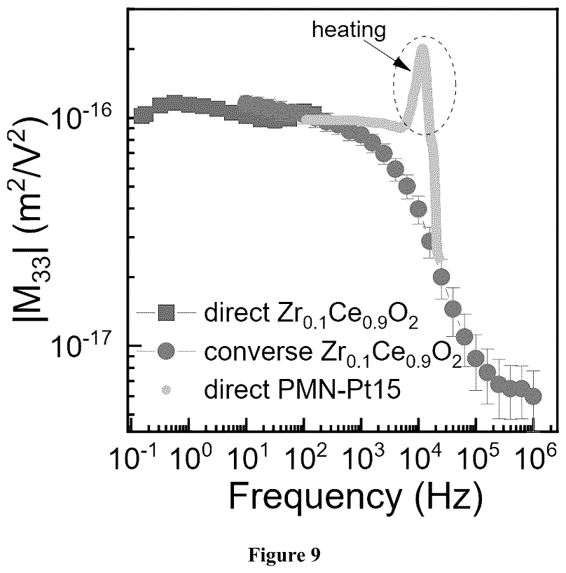

*electrostriction coefficient values in this table are frequency independent.
FIG. 9 presents comparison of the longitudinal electrostriction coefficient, M33, Zr_{0.1}Ce_{0.9}O₂ with the best commercial electrostrictor PMN-PT.

In one embodiment, materials of this invention have a dielectric constant lower than conventional lead-based materials. Such lower dielectric constant is an advantage because this means the material will require less current to operate. Compared with conventional materials, ceria is easier to deposit as a thin film or to make as a pellet. It also does not require poling. In one embodiment, materials of this invention are lead free. In one embodiment, materials of this invention have higher young's modulus.

### Dielectric Permittivity

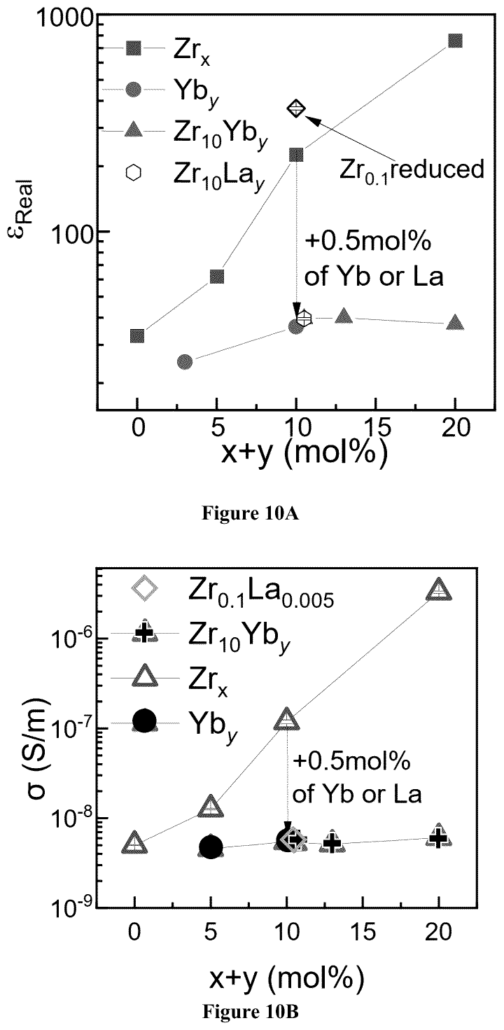

Doping ceria with Zr increased both the dielectric permittivity (εᵣ, real part) and electrical conductivity, σ. At 100 Hz, εᵣ of undoped oxidized ceria sample is εCeO₂^{(100Hz)} ≈32±(5%), which was also close to the dielectric constant of pure ZrO₂. However, doping with Zr, increased both and εᵣ and σ: ε_{Zr0.05Cc0.9502}^{(100Hz)}=62±1 and ϵ_{zr0.1Ce0.902}^{(100H=)}=224±2 for oxidized samples with <100 ppm of Ce³⁺ ions (FIG. 10A). σ of oxidized samples at 100 Hz increased even more dramatically: up to two orders of magnitude for Zr_{0.1}Ce_{0.9}O₂, with respect to CeO₂ (FIG. 10B).

Doping Zr_{0.1}Ce_{0.9}O₂ with 0.5 mol % of La or Yb reduced εᵣ and the electrical conductivity back to the values close to undoped ceria and other rare-earth doped ceria, suggesting that increase in M33, enhancement of εᵣ and σ upon introduction of zirconia into ceria have the same microscopic origin. Further increase in Yb content to 10 mol % does not affect εᵣ and σ.

### Elastic Properties

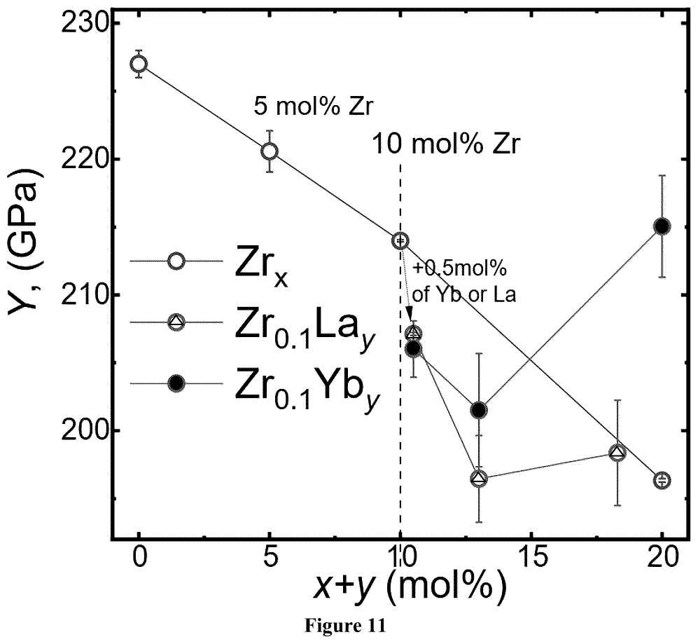

Introduction of Zr decreased elastic modulus, Y, (FIG. 11) linearly with Zr-content from 227±1 GPa (pure ceria) to 213≈0.08 GPa (10 mol % Zr), i.e., 0.62±0.04 per mol of the dopant even though Zr-doping did not decrease the number of the chemical bonds in the lattice. However, adding just 0.5% of Yb brought the elastic modulus to 207±0.1 GPa and adding 0.5% of La to 206±2 GPa, which a ten-fold faster rate of decrease 5.6 mol-1 and 6.6 mol⁻¹ (FIG. 11). This indicates that as it is for the case of M33 and Er, even a small concentration of oxygen vacancies causes a major change in properties. Further increase in La and Yb content have profoundly different effect on Y (FIG. 11): Yb caused steep increase at 10 mol % after a minimum at 5 mol %, which correlates with the change in the lattice parameter. Co-doping with La caused drop in Y at 5 mol % and no further changes even though it causes increase in the lattice parameter.

### CONCLUSION

The majority of commonly used electrostrictive ceramics are based on lead manganese niobate. These ceramics display large electrostriction strain coefficients ˜10⁻¹⁶ m²/V² at frequencies up to a few kHz; however, they suffer from two major drawbacks: large dielectric constants (>10000), which require high driving currents, and incompatibility with thin-film Si-microfabrication techniques. Aliovalent doped ceria exhibits electrostriction coefficients >100-fold larger than estimated on the basis of Newnham's scaling law for classical electrostrictors, despite ceria's large Young's modulus (˜200 GPa) and low dielectric constant (<30). This “non-classical” behavior has been attributed to the formation of highly polarizable, elastic dipoles reorienting under external electric field. It was herein demonstrated that oxidized, 10 mol % Zr⁴⁺-doped ceria displays |M| ˜10⁻¹⁶ m²/V² throughout the 0.1-3000 Hz frequency range. See Table 1 herein above. However, practical application of these ceramics may be hindered by the relatively large, room-temperature electrical conductivity (10⁻¹⁰ S/m), a result of the formation of Ce³⁺ which can promote electron hopping. Formation of Ce³⁺ also raises the dielectric constant to ≈200. Suppression of Ce³⁺ by co-doping reduces the dielectric constant to ˜30 but also reduces the electrostriction constant to ˜10⁻¹⁷ m²/V². The results presented herein imply that by systematically adjusting the composition of ceria-based solid solutions, the development of technologically useful electrostrictive materials is possible. Materials which are at the same time fully compatible with Si-microfabrication.

### Example 2

### The Mechanism of Electrostriction

Based on M33, Y and εᵣ from FIGS. 2A-2E, FIGS. 10A-10B and FIG. 11, ceramics with the composition Zr_{0.1}Yb_{0.1}Ce_{0.8}O_{1.95} has M₃₃ at least more than 580 times higher than that expected from the Newnham's scaling law, while for Zr_{0.1}Ce_{0.9}O₂, this factor is only 135. This is because although the former the 3.5 lower M33 than the latter, the former also has six-fold lower ratio M33/Er, which is important for practical applications: for Zr_{0.1} Yb_{0.1}Ce_{0.8}O_{1.95}, M33/εᵣ is 0.75 (nC/N)₂ while for Zr_{0.1}Ce_{0.9}O₂ it is only 0.44 (nC/N)₂.

The electrostriction in the doped ceria arises due to chemical bond stiffness constant mismatch between the 8-coordinate dopant and the host. Therefore, the oxygen trapping explain:
1. Increase in M33 in the line Nd, Sm, Gd, Er, Yb, Lu, Zr: the smaller the dopant crystal radii is the larger is the difference in the bond stiffness constants between the host and the guest. Zr is the smallest and has the highest M33.
2. The drastic decrease in M33 upon adding 0.5 mol % of Yb or La to Zr0.1Ce0.9O2: Zr traps oxygen vacancies (VO) better than Yb and La. Therefore, [ZrO8] bonding unit becomes [ZrO7-VO], which does not participate in electrostriction response.
3. Adding 10 mol % of Zr to Y_{0.1}Ce_{0.9}O_{1.95} increases M33 because Zr traps VO from Y, increasing the number of [YbO8] units. Without Zr only ˜50% of Yb-dopant ions are active because Yb introduces VO (two Y generate one vacancy), detrimental for electrostriction.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A ceria-based material, doped by a metal M, said metal M is selected from Hf, Zr and Ti, wherein upon application of an electric field said ceria-based material generates displacement, stress or a combination thereof, wherein the electrostriction coefficient of said material ranges between 10⁻¹⁵ m²/V² and 10⁻¹⁸ m²/V² at a frequency ranging between 0.1 Hz and 105 Hz.

2. The material of claim 1, wherein said material is represented by the formula Ce₁₋ₓ MₓO_{2-d} wherein x ranges between 0.02 and 0.7 and d ranges between 0 and 0.03.

3. The material of claim 1, co-doped with a metal with a lower valence than said metal M.

4. The material of claim 3, wherein said metal with a lower valence is selected from: Ca, Mg, Fe, Sc, Sn and Y or combinations thereof.

5. The material of claim 3, wherein said metal with a lower valence comprises a lanthanide L.

6. The material of claim 4, wherein said lanthanide L is any lanthanide selected from La, Pr, Nd, Pm, Sm, Eu, Gd, Tb, Dy, Ho, Er, Tm, Yb and Lu or any combination thereof.

7. The material of claim 6, wherein said ceria-based material is represented by the formula Ce_{1-x-y}MₓL_{y}O_{2-y/2-d}, and wherein said x ranges between 0.01-0.7 and said y range between 0.01-0.7 and said d ranges between 0 and 0.03.

8. The material of claim 7, wherein L is La or Yb.

9. The material of claim 8, wherein L is La, x=0.10±0.02 and y ranges between 0.01 and 0.08, or wherein L is Yb, x=0.10±0.02 and y ranges between 0.05 and 0.15.

10. The material of claim 1, wherein said displacement ranges between 0.1 ppm and 500 ppm.

11. The material of claim 1, wherein said stress is at least 0.01 MPa.

12. The material of claim 1, with a Young's modulus which ranges between 100 GPa and 250 GPa.

13. The material of claim 1, wherein said electrostriction coefficient is frequency independent.

14. The material of claim 1, with a dielectric constant which ranges between 10 and 1000.

15. The material of claim 1, with an electrical conductivity which ranges between 10⁻⁹ S/m and 10⁻⁵ S/m.

16. The material of claim 1, in a material form selected from: a disk, a film, a powder, a bar, a pellet or any combinations thereof.

17. A process for making the material of claim 1, said process comprising:
a. adding an alkaline aqueous solution to an aqueous solution containing Ce ions, ions of metal M and optionally ions of a metal L;
b. keeping the resulting mixture at an elevated temperature, optionally while stirring, for a period of time of at least 25 mins; and
c. optionally washing the resulted precipitate.

18. The process of claim 17, wherein the origin of the Ce ions, the metal M ions and optionally the metal Lions is a salt of said ions.

19. The process of claim 18, wherein the salts of said ions are Ce(NO₃)₃·6H₂O, ZrO(NO₃)₂·6H₂O, and optionally L(NO₃)₃·6H₂O.

20. The process of claim 17, wherein said alkaline aqueous solution comprises (NH₄)₂CO₃.

21. The process of claim 17, wherein the resultant precipitate is a powder, and wherein said powder is ground and optionally calcined.

22. The process of claim 21, wherein said powder undergoes pressing in a mold or die, resulting in the formation of a disk, bar or a pellet.
